(19) United States
(12) Patent Application Publication
(10) Pub. No.: US 2011/0062474 A1
(43) Pub. Date: Mar. 17, 2011

(54) LIGHT-EMITTING DIODE DEVICE AND FABRICATION METHOD THEREOF

(75) Inventors: Pin Chuan Chen, Hsinchu County (TW); Chao Hsiung Chang, Hsinchu County (TW); Shen Bo Lin, Hsinchu County (TW); Wen Liang Tseng, Hsinchu County (TW)

(73) Assignee: ADVANCED OPTOELECTRONIC TECHNOLOGY INC., Hsinchu County (TW)

(21) Appl. No.: 12/879,255

(22) Filed: Sep. 10, 2010

(30) Foreign Application Priority Data
Sep. 14, 2009 (CN) 200910169996.8

(51) Int. Cl. H01L 33/58; H01L 33/62

(52) U.S. Cl. 257/98; 438/27; 257/E33.067

(57) ABSTRACT

A light-emitting diode device includes a frame, a light-emitting diode die, a fluorescent layer, a reflector, and a lens. The light-emitting diode die is disposed on the frame. The fluorescent layer is directly molded to cover the light-emitting diode die. The reflector is directly molded on the frame, surrounding the light-emitting diode die, and configured to direct light from the light-emitting die in a predetermined direction. The lens is directly molded within the reflector, covering the fluorescent layer.

### BACKGROUND OF THE INVENTION

1. Field of the Invention

The present invention relates to a light-emitting diode device and a fabrication method thereof, and more particularly to a light-emitting diode device fabricated using an injection molding technique or a transfer molding technique and the fabrication method thereof.

2. Description of the Related Art

A typical light-emitting diode (LED) device includes a lead frame, an LED die, a transparent layer, a reflecting cup, and a lens. The frame includes a mounting pad, on which the LED die is placed. A portion of the lead frame is formed within the reflecting cup having an opening, over which the lens is attached. The transparent layer is disposed in the lens, is covering the LED die.

The above-mentioned lens is pre-molded, and then is manually aligned with and fastened over the opening. U.S. Pat. No. 7,456,499, U.S. Pat. No. 6,274,924, and U.S. Pat. No. 7,458,703 all disclose analogous LED devices including pre-molded lenses. However, manual assembly of the lens may increase manufacturing time and cost, and precise manual assembly operations are not easily maintained, resulting in low production yields.

Further, the reflecting cup, the transparent layer, and the lens are formed in different fabricating steps and using different molds. As such, the fabricating procedure of the typical LED devices is complex. A complex fabricating procedure is not easily managed, and may cause low yield and high production cost.

In view of the above-mentioned issues, a new LED device having no such issues is required.

### SUMMARY OF THE INVENTION

To avoid the above-mentioned issues, the present invention provides a light-emitting diode device formed using an injection molding technique or a transfer molding technique and a fabrication method thereof.

One embodiment of the present invention provides a light-emitting diode device, which includes a frame, a light-emitting diode die, a fluorescent layer, a reflector, and a lens. The light-emitting diode die is disposed on the frame. The fluorescent layer is molded to cover the light-emitting diode die. The reflector is molded on the frame, surrounding the light-emitting diode die, wherein the reflector is configured to direct light in a predetermined direction. The lens is molded within the reflector, covering the fluorescent layer.

The present invention discloses a fabrication method of a light-emitting is diode device, which comprises the steps of: providing a frame; disposing a light-emitting diode die on the frame; molding a fluorescent layer covering the light-emitting diode; molding a reflector disposed on the frame, surrounding the light-emitting diode die, and configured to direct light in a predetermined direction; and molding a lens, covering the fluorescent layer, in the reflector.

To better understand the above-described objectives, characteristics and advantages of the present invention, embodiments, with reference to the drawings, are provided for detailed explanations.

### BRIEF DESCRIPTION OF THE DRAWINGS

The invention will be described according to the appended drawings in which:

FIG. 1 is a stereoscopic view illustrating a light-emitting diode device according to one embodiment of the present invention;

FIG. 2 is a top view of the light-emitting diode device of FIG. 1;

FIG. 3 is a cross-sectional view along line A-A of FIG. 1;

FIG. 4 is an upward view showing a frame according to one embodiment of the present invention;

FIG. 5 is a cross-sectional view showing a light-emitting diode device according to an alternative embodiment of the present invention;

FIG. 6 is a cross-sectional view showing a light-emitting diode device according to an alternative embodiment of the present invention;

FIG. 7 is a cross-sectional view showing a light-emitting diode device according to an alternative embodiment of the present invention; and

FIG. 8 is a flow chart showing the fabrication method of a light-emitting diode device according to one embodiment of the present invention.

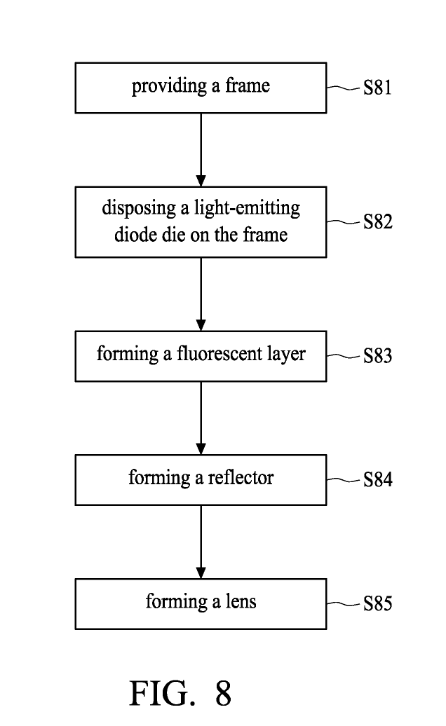

### DETAILED DESCRIPTION OF THE INVENTION

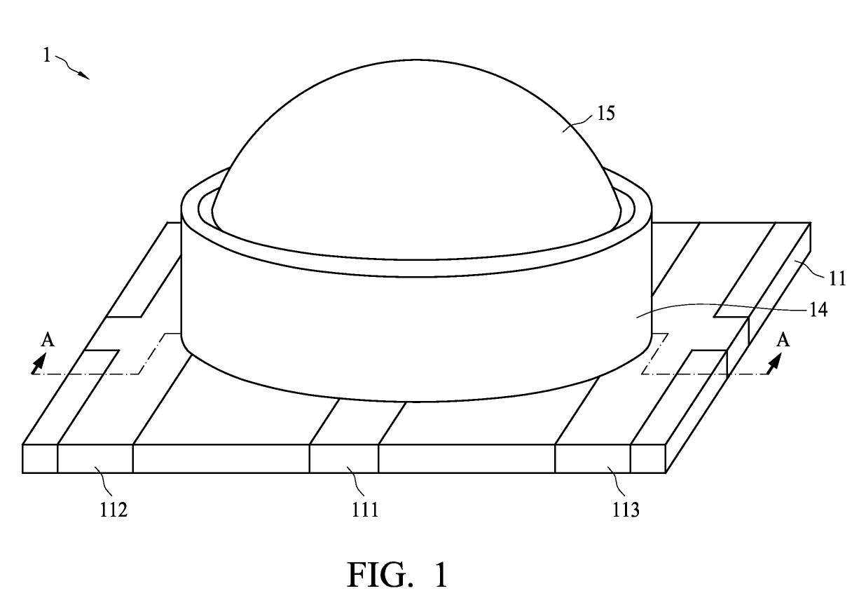

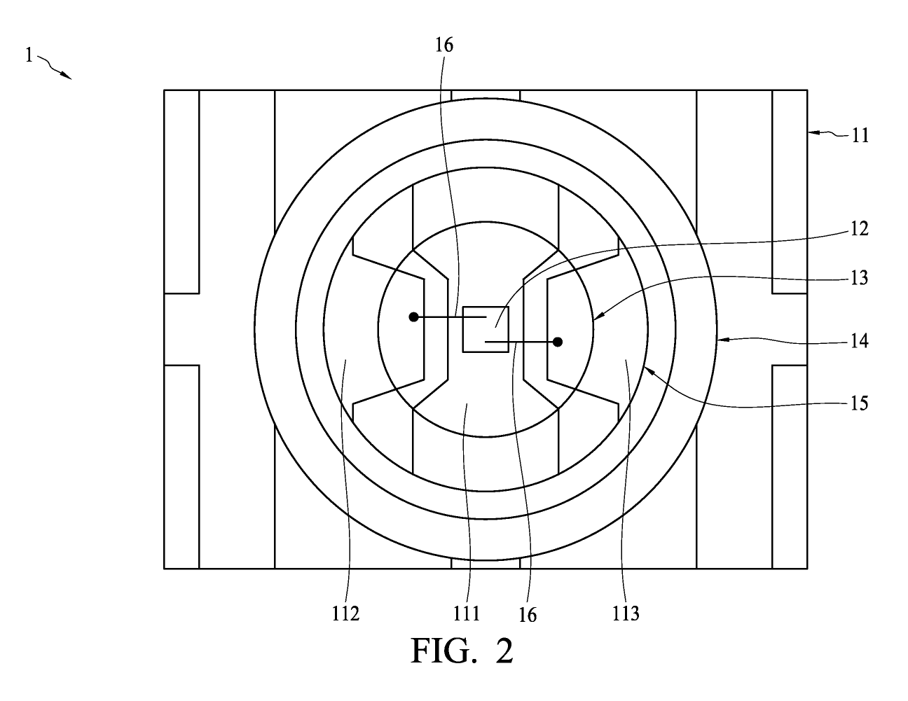

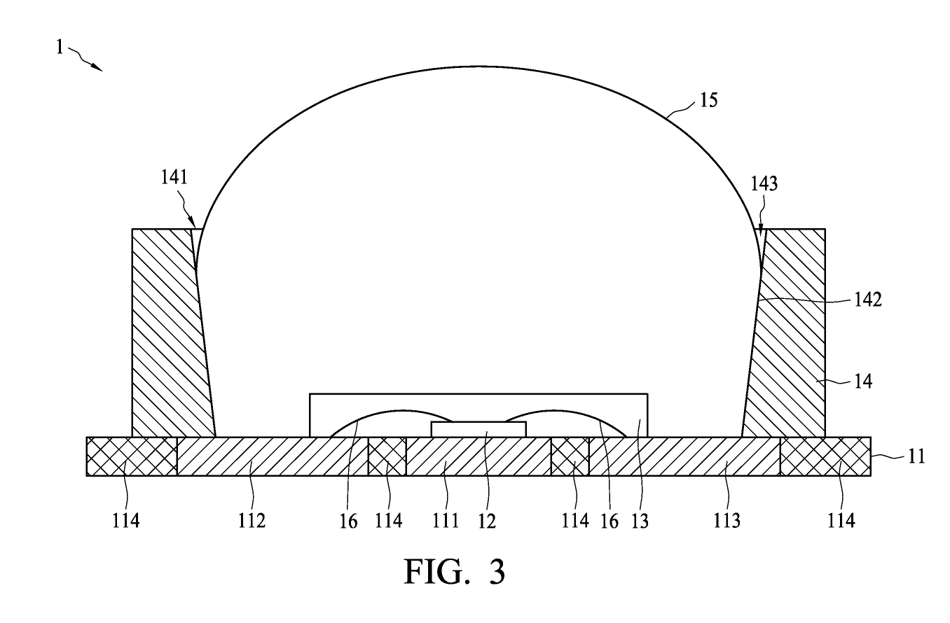

FIG. 1 is a stereoscopic view illustrating a light-emitting diode device 1 according to one embodiment of the present invention; FIG. 2 is a top view of the light-emitting diode device 1 of FIG. 1; and FIG. 3 is a cross-sectional view along line A-A of FIG. 1. Referring to FIGS. 1 to 3, in one embodiment of the present invention, a light-emitting diode device 1 comprises a frame 11, a light-emitting diode (LED) die 12, a fluorescent layer 13, a reflector 14, and a lens 15. The LED die 12 is disposed on the frame 11 so as to obtain support. The fluorescent layer 13 is molded over the LED die 12, covering the LED die 12. The reflector 14 is molded on the frame 11 and surrounds the LED die 12. The reflector 14 has an opening 141, wherein light radiated from the LED die 12 passes through the opening 141 to the exterior of the light-emitting diode device 1. The lens 15 is molded within the reflector 14 and covers the fluorescent layer 13.

Referring to FIG. 2, the frame 11 may comprise a die support 111, a first electrode 112, and a second electrode 113. The LED die 12 is disposed on the die support 111 so as to be supported. In addition, the die support 111 can be of high thermal conductivity; thus heat from the LED die 12 can be dissipated by the die support 111 so as to improve the heat dissipation efficiency of the LED die 12, to lower the operating temperature of the LED die 12, and to increase the lifespan of the LED die 12. The first electrode 112 and the second electrode 113 are separately disposed on two opposite sides of the die support 111 and are configured to allow the LED die 12 to electrically connect to an external power source.

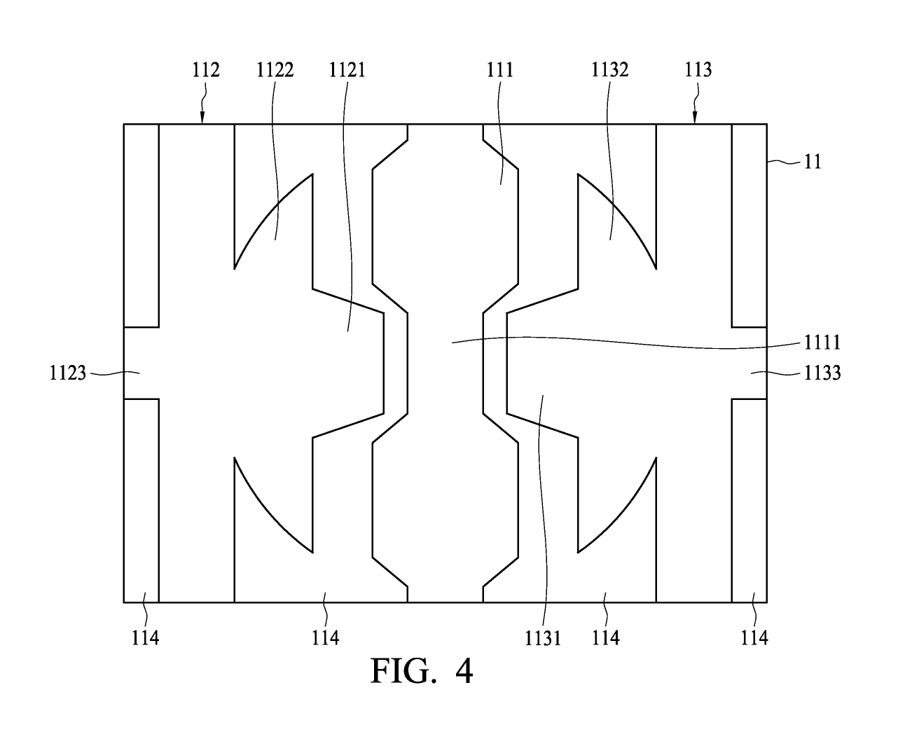

Specifically, referring to FIG. 4, the die support 111 may include a reduced section 1111 formed around the middle of the die support 111. The LED die 12 is disposed on the reduced section 1111. The width of the reduced section 1111 may be adapted to match the size of the LED die 12. Each of the first electrode 112 and the second electrode 113 may include a protruding section 1121 or 1131 protruding adjacent to the corresponding edges of the reduced section 1111. The matched design of the reduced section 1111 and the two protruding sections 1121 and 1131 may reduce the distances between the LED die 12 and the first and second electrodes 112 and 113.

In addition, in one embodiment of the present invention, each protruding section 1121 or 1131 can protrude from a corresponding connecting section 1122 or 1132, which can have a shallow circular segment shape and are disposed within the reflector 14. The die support 111 and the connecting sections 1122 and 1132 are configured to occupy the most area delineated by the reflector 14 so that the light-emitting diode device 1 may have high heat dissipation efficiency. Each of the first and second electrodes 112 and 113 may separately include an externally extended section 1123 or 1133 extending externally from a side of the corresponding connecting sections 1122 or 1132 opposite to the protruding section 1121 or 1131, wherein the externally extended sections 1123 and 1133 are disposed outside the reflector 14. In addition, the frame 11 may further comprise a dielectric portion 114 disposed between the first and second electrodes 112 and 113 and the die support 111. The dielectric portion 114 is provided to electrically insulate the first and second electrodes 112 and 113 from the die support 111. As such, the light-emitting diode device 1 has a thermally and electrically separated structure.

In one embodiment of the present invention, the LED die 12 can be wired to the protruding sections 1121 and 1131 using wires 16 for electrical connection.

In one embodiment of the present invention, the material of the first and second electrodes 112 and 113 and die support 111 can be copper. The LED die 12 can be a laser diode, III-V group compound semiconductor light-emitting diode, or II-VI group compound semiconductor light-emitting diode.

The inner surface of the reflector 14 facing the LED die 12 is an inclined surface 142 defining an accommodation space 143 having a cross section, parallel to the frame 11, which gradually increases from a location adjacent to the frame 11 to a location adjacent to the opening 141. In one embodiment of the present invention, the reflector 14 has a cup-like shape. The diameters of the cross sections of the accommodation space 143 increase along a direction from the frame 11 to the opening 141. Light from the LED die 12 is reflected by the inclined surface 142, passing through the opening 141 toward the outside of the light-emitting diode device 1.

The reflector 14 can be directly molded on the frame 11. In other words, the reflector 14 can be directly formed on the frame 11 using an injection molding technique or a transfer molding technique. The reflector 14 is not independently formed and then attached to the frame 11. Because the frame 11 is made of metal, the frame 11 has high strength property, so the frame 11 can withstand the pressure used in an injection molding process or a transfer molding process. Therefore, the reflector 14 of the light-emitting diode device 1 can be directly molded on the frame 11. In one embodiment of the present invention, the reflector 14 can include silicone resin and white particles, wherein the white particle can be silicon dioxide.

Referring to FIG. 3, the fluorescent layer 13 configured to cover the LED die 12 may include fluorescent powder uniformly dispersed within the fluorescent layer 13. The fluorescent powder can be excited by a portion of light emitted from the LED die 12, generating complimentary light, and the complementary light can mixed with another portion of light to allow the light-emitting diode device 1 to generate white light. In one embodiment of the present invention, the fluorescent layer 13 may comprise a transparent polymer, wherein the polymer can be epoxy resin, silicone resin or a hybrid thereof. The fluorescent layer 13 can be directly molded on the frame 11. Namely, the fluorescent layer 13 can be directly formed on the frame 11 using an injection molding technique or a transfer molding technique.

Referring to FIG. 3, the lens 15 can be directly molded within the reflector 14, covering the whole fluorescent layer 13. Further, the lens 15 can also be directly formed on the frame 11, in the accommodation space 143 of the reflector 14 using an injection molding technique or a transfer molding technique. In one embodiment of the present invention, the material of the lens 15 can be transparent silicone resin.

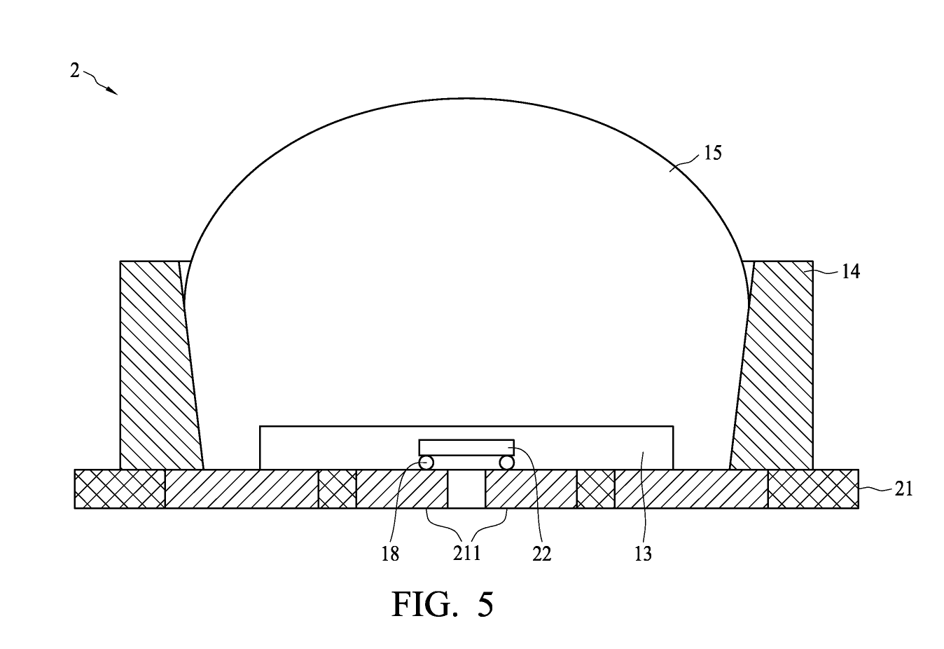

FIG. 5 is a cross-sectional view showing a light-emitting diode device 2 according to an alternative embodiment of the present invention. In another embodiment of the present invention, the light-emitting diode device 2 may comprise a frame 21, an LED die 22, a fluorescent layer 13, a reflector 14, and a lens 15. The frame 21 may include two electrodes 211. The LED die 22 is disposed on the frame 21, flip-chip bonded to the two electrodes 211 by bumps 18. The fluorescent layer 13 is molded over the LED die 22, covering the LED die 22. The reflector 14 is molded on the frame 21, surrounding the LED die 22. The reflector 14 has an opening, through which light is emitted from the LED die. The lens 15 is molded within the reflector 14, covering the fluorescent layer 13.

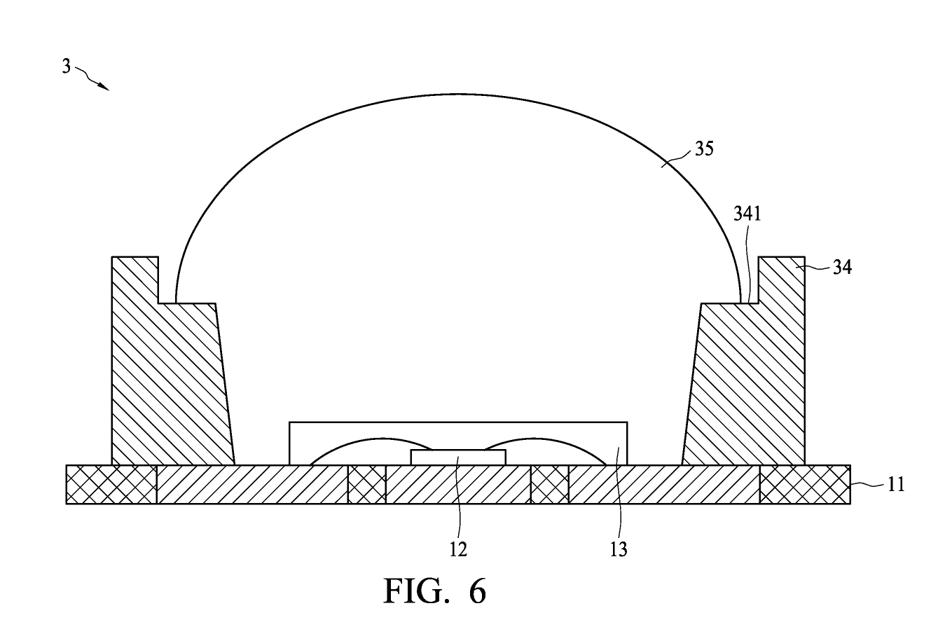

FIG. 6 is a cross-sectional view showing a light-emitting diode device 3 according to an alternative embodiment of the present invention. In another embodiment of the present invention, the light-emitting diode device 3 comprises a frame 11, an LED die 12, a fluorescent layer 13, a reflector 34, and a lens 35. The LED die 12 is disposed on the frame 11 to obtain support. The fluorescent layer 13 is molded over the LED die 12, covering the LED die 12. The reflector 34 is molded on the frame 11, surrounding the LED die 12. The reflector 11 has an opening, through which light is emitted from the LED die. The reflector 34 includes a stepped surface 341, formed inside the reflector 34. The lens 35 is molded within the reflector 34, covering the fluorescent layer 13, wherein the lens 35 can cover a portion of the stepped surface 341.

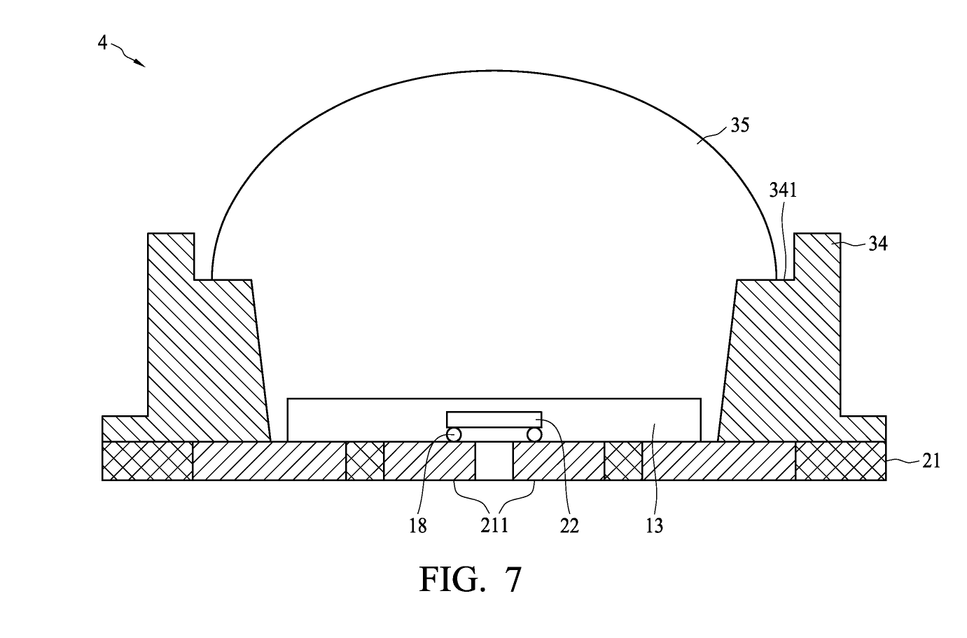

FIG. 7 is a cross-sectional view showing a light-emitting diode device 4 according to an alternative embodiment of the present invention. In another embodiment of the present invention, the light-emitting diode device 4 comprises a frame 21, an LED die 22, a fluorescent layer 13, a reflector 34, and a lens 35. The frame 21 comprises two electrodes 211. The LED die 22 is disposed on the frame 21, flip-chip bonded to the two electrodes 211 by bumps 18. The fluorescent layer 13 is molded over the LED die 22, covering the LED die 22. The reflector 14 is molded on the frame 21, surrounding the LED die 22. The reflector 14 has an opening, through which light is emitted from the LED die. The reflector 34 includes a stepped surface 341, formed inside the reflector 34. The lens 35 is molded within the reflector 34, covering the fluorescent layer 13, wherein the lens 35 can cover a portion of the stepped surface 341.

The present invention provides a fabrication method of a light-emitting diode device. In Step S81, a frame is initially provided. In Step S82, an LED die is disposed on the frame. In one embodiment, the frame includes a die support and two electrodes, wherein the LED die is disposed on the die support, electrically connecting to the two electrodes using wires. In another embodiment, the frame includes two electrodes, and the LED die is flip-chip bonded to the two electrodes. In one embodiment of the present invention, the electrode comprises a gold coated copper electrode or a silver coated copper electrode, and the die support comprises a gold coated copper die support or a silver coated copper die support. In Step S83, the fluorescent layer is molded on the LED die, wherein the fluorescent layer can be formed using an injection molding technique or a transfer molding technique. In Step S84, a reflector is molded on the frame, surrounding the LED die. The reflector is configured to direct light in a predetermined direction. The reflector can be formed using an injection molding technique or a transfer molding technique. In Step S85, a lens is molded within the reflector, covering the fluorescent layer. The lens can be formed using an injection molding technique or a transfer molding technique.

In summary, a light-emitting diode device comprises a frame, an LED is die, a fluorescent layer, a reflector, and a lens. The LED die is disposed on the frame, which is mainly constituted of metal so as to improve the heat dissipation of the LED die. Because the frame is mainly constituted of metal, the fluorescent layer, the reflector, and the lens can be molded directly on the frame using an injection molding technique or a transfer molding technique. As such, the assembly alignment procedure and some assembly steps used for assembling typical light-emitting diode devices are not needed.

Clearly, following the description of the above embodiments, the present invention may have many modifications and variations. Therefore, the scope of the present invention shall be considered with the scopes of the dependent claims. In addition to the above detailed description, the present invention can be broadly embodied in other embodiments. The above-described embodiments of the present invention are intended to be illustrative only, and should not become a limitation of the scope of the present invention. Numerous alternative embodiments may be devised by persons skilled in the art without departing from the scope of the following claims.

What is claimed is:

1. A light-emitting diode device, comprising:
a frame;
a light-emitting diode die disposed on the frame;
a fluorescent layer molded to cover the light-emitting diode die;
a reflector molded on the frame, surrounding the light-emitting diode die, configured to direct light in a predetermined direction; and
a lens molded within the reflector, covering the fluorescent layer.

2. The light-emitting diode device of claim 1, wherein the fluorescent layer, the reflector, and the lens are formed using an injection molding technique or a transfer molding technique.

3. The light-emitting diode device of claim 1, wherein the frame comprises a die support, on which the light-emitting diode die is disposed.

4. The light-emitting diode device of claim 3, wherein the frame comprises two electrodes respectively wired to the light-emitting diode die.

5. The light-emitting diode device of claim 1, wherein the frame includes two electrodes, to which the light-emitting diode die is flip-chip bonded.

6. The light-emitting diode device of claim 1, wherein the material of the frame is copper.

7. The light-emitting diode device of claim 1, wherein the material of the fluorescent layer is fluorescent powder and polymer resin, which is epoxy resin, silicone resin, or a hybrid thereof.

8. The light-emitting diode device of claim 1, wherein the material of the reflector is silicone resin and white particles including silicon dioxide.

9. The light-emitting diode device of claim 1, wherein the material of the lens is silicone resin.

10. The light-emitting diode device of claim 1, wherein the light-emitting diode die is a laser diode, III-V group compound semiconductor light-emitting diode, or II-VI group compound semiconductor light-emitting diode.

11. A fabrication method of a light-emitting diode device, comprising the steps of:
providing a frame;
disposing a light-emitting diode die on the frame;
molding a fluorescent layer covering the light-emitting diode;
molding a reflector disposed on the frame, surrounding the light-emitting diode die, and configured to direct light in a predetermined direction; and
molding a lens, covering the fluorescent layer, in the reflector.

12. The fabrication method of claim 11, wherein the fluorescent layer, the reflector, and the lens are formed using an injection molding technique or a transfer molding technique.

13. The fabrication method of claim 11, wherein the frame comprises a die support, on which the light-emitting diode die is disposed.

14. The fabrication method of claim 13, wherein the frame comprises two electrodes respectively wired to the light-emitting diode die.

15. The fabrication method of claim 11, wherein the frame includes two electrodes, to which the light-emitting diode die is flip-chip bonded.

16. The fabrication method of claim 11, wherein the material of the frame is copper.

17. The fabrication method of claim 11, wherein the material of the fluorescent layer is fluorescent powder and polymer resin, which is epoxy resin, silicone resin, or a hybrid thereof.

18. The fabrication method of claim 11, wherein the material of the reflector is silicone resin and white particles including silicon dioxide.

19. The fabrication method of claim 11, wherein the material of the lens is silicone resin.

20. The fabrication method of claim 11, wherein the light-emitting diode die is a laser diode, III-V group compound semiconductor light-emitting diode, or II-VI group compound semiconductor light-emitting diode.
